(19) United States
(12) Patent Application Publication
(10) Pub. No.: US 2018/0323338 A1
(43) Pub. Date: Nov. 8, 2018

(54) ULTRAVIOLET LIGHT EMITTING DIODE WITH TUNNEL JUNCTION

(71) Applicant: X Development LLC, Mountain View, CA (US)

(72) Inventors: Michael Grundmann, San Jose, CA (US); Martin F. Schubert, Mountain View, CA (US)

(21) Appl. No.: 15/587,269

(22) Filed: May 4, 2017

(51) Int. Cl. H01L 33/06; H01L 33/32; H01L 27/15; H01L 25/16; H01L 33/00; H05B 33/08

(52) U.S. Cl. CPC H01L 33/06; H01L 33/32; H05B 33/0803; H01L 25/167; H01L 33/0025; H01L 27/156

(57) ABSTRACT

A light emitting diode (LED) to emit ultraviolet (UV) light includes a first n-type semiconductor region and a first p-type semiconductor region. The LED also includes an active region disposed between the first n-type semiconductor region and the first p-type semiconductor region, and in response to a bias applied across the light emitting diode, the active region emits UV light. A tunnel junction is disposed in the LED so the first p-type semiconductor region is disposed between the active region and the tunnel junction. The tunnel junction is electrically coupled to inject charge carriers into the active region through the first p-type semiconductor region. A second n-type semiconductor region is also disposed in the LED so the tunnel junction is disposed between the second n-type semiconductor region and the first p-type semiconductor region.

### TECHNICAL FIELD

This disclosure relates generally to light emitting diodes.

### BACKGROUND INFORMATION

Ultraviolet (UV) light loosely refers to electromagnetic radiation with a wavelength of 10 nm to 420 nm, this wavelength range is shorter than that of visible light but longer than X-rays. UV light is emitted from the sun and is approximately 10% of the sun's total output. Light in the UV spectrum can cause chemical reactions in organic molecules; accordingly UV light can cause significant biological effect (most notably sun burn).

Due to UV light's ability to induce chemical reaction and cause materials to fluoresce, UV radiation has a number of applications. For example, light in the ˜10 nm wavelength range may be used for extreme UV lithography, light in the 230-265 nm wavelength range may be used for label tracking and bar codes, and light in the 280-400 nm wavelength range may be used for the medical imaging of cells.

Because UV light has many useful applications, devices that emit UV light are in demand. However, many of these UV sources may suffer from the same deficiencies as conventional light bulbs: they are large, inefficient, fragile, and cannot be used as optical point sources. For example, some common UV emitters are short wavelength fluorescent tube lamps and gas discharge lamps, both of which use an evacuated tube to produce UV light. Accordingly, in order to better integrate UV emitting devices into beneficial applications, small compact devices need to be developed.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. The drawings are not necessarily to scale, emphasis instead being placed upon illustrating the principles being described.

FIG. 1 is an illustration of an ultraviolet light emitting diode, in accordance with an embodiment of the disclosure.

FIG. 2A is an illustration of a tunnel junction for the ultraviolet light emitting diode in FIG. 1, in accordance with an embodiment of the disclosure.

FIG. 2B is an illustration of a tunnel junction for the ultraviolet light emitting diode in FIG. 1, in accordance with an embodiment of the disclosure.

FIG. 2C is an illustration of a tunnel junction for the ultraviolet light emitting diode in FIG. 1, in accordance with an embodiment of the disclosure.

FIG. 2D is an illustration of a tunnel junction for the ultraviolet light emitting diode in FIG. 1, in accordance with an embodiment of the disclosure.

FIG. 3 is an illustration of a tunnel junction and accompanying band diagrams for the ultraviolet light emitting diode in FIG. 1, in accordance with an embodiment of the disclosure.

FIG. 4 is an illustration of a system for ultraviolet light emission which may contain the ultraviolet light emitting diode in FIG. 1, in accordance with an embodiment of the disclosure.

FIG. 5 illustrates a method of emitting ultraviolet light, in accordance with an embodiment of the disclosure.

FIGS. 6A-6D illustrate ternary composition diagrams for tunneling layers for several of the tunnel junction architectures depicted, in accordance with several embodiments of the disclosure.

### DETAILED DESCRIPTION

Embodiments of an apparatus and method for an ultraviolet light emitting diode with a tunnel junction are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

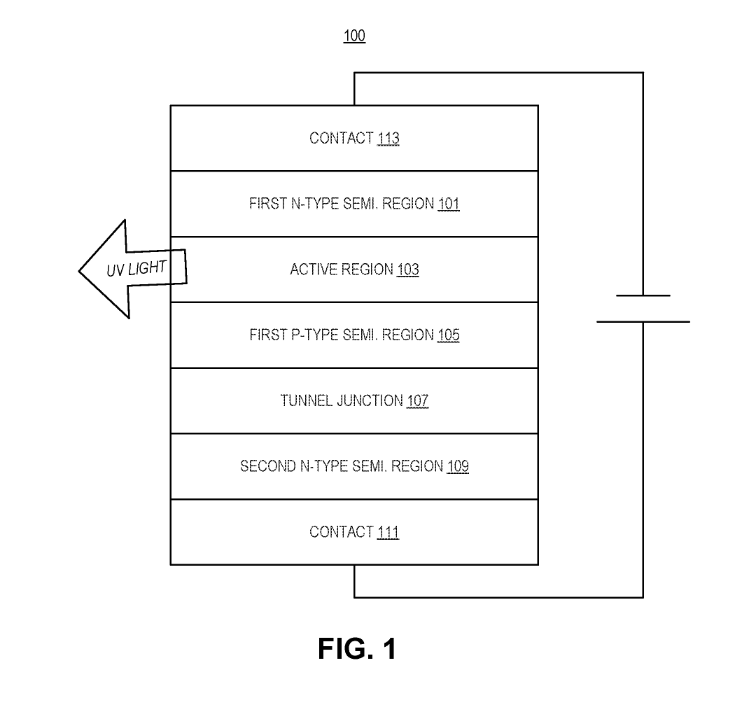

FIG. 1 is an illustration of an ultraviolet (UV) light emitting diode (LED) 100, in accordance with an embodiment of the disclosure. UV LED 100 includes (from top of page to bottom) first contact 113, first n-type semiconductor region 101, active region 103, first p-type semiconductor region 105, tunnel junction 107, second n-type semiconductor region 109, and second contact 111. As depicted, in response to an applied voltage, the active region of UV LED 100 emits UV light. In some embodiments more than 50% of the spectrum emitted by UV LED 100 is UV light. Also, as one of ordinary skill in the art will appreciate, UV LED 100 may emit any other wavelength of light depending on the specific device architecture employed.

As illustrated, active region 103 is disposed between first n-type semiconductor region 101 and first p-type semiconductor region 105. First p-type semiconductor region 105 is disposed between active region 103 and tunnel junction 107. Tunnel junction 107 is electrically coupled to inject charge carriers into active region 103 through first p-type semiconductor region 105. Tunnel junction 107 is disposed between second n-type semiconductor region 109 and first p-type semiconductor region 105. First electrical contact 113 is coupled to first n-type semiconductor region 101, and second electrical contact 111 is coupled to second n-type semiconductor region 109.

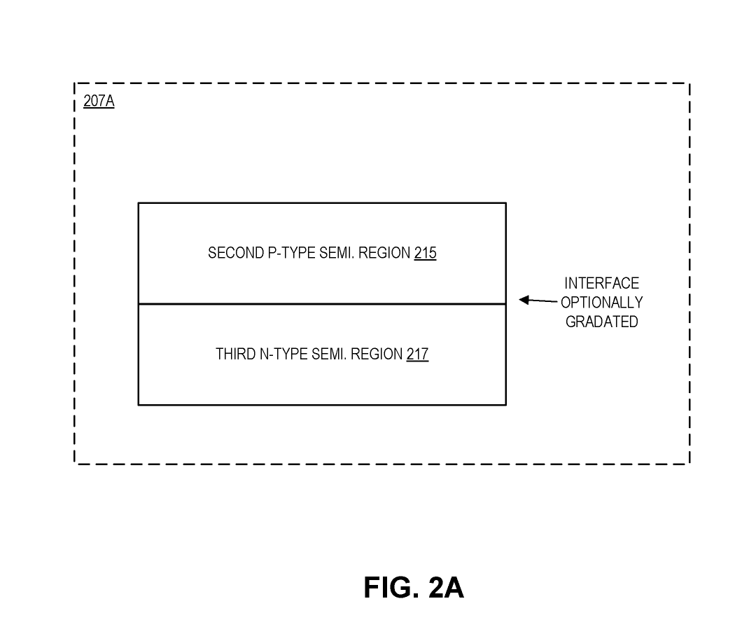

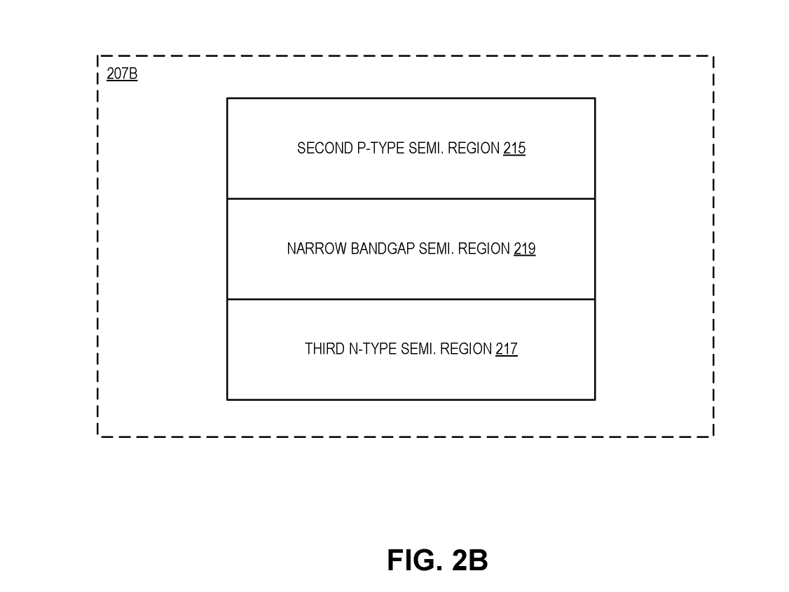

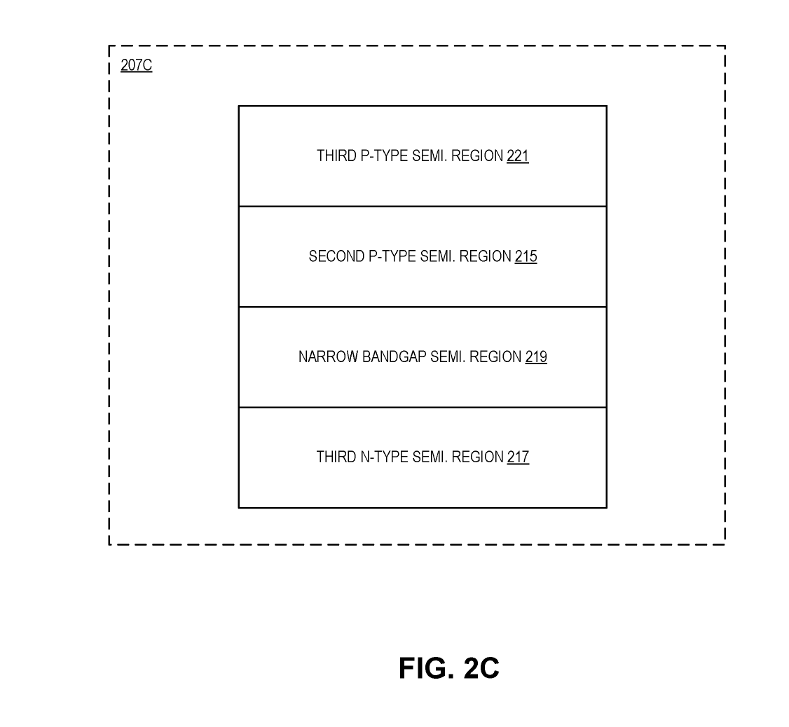

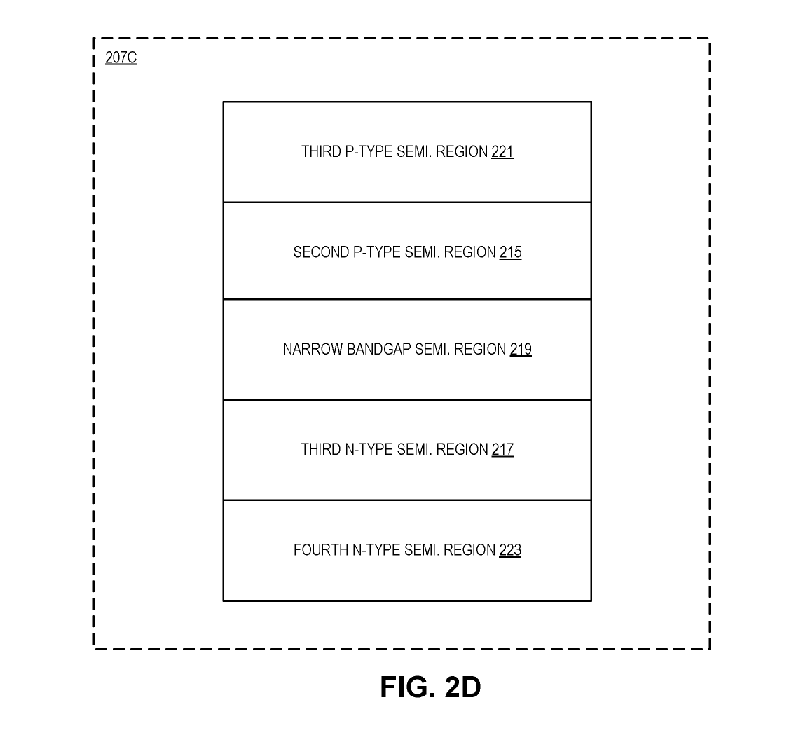

In the depicted embodiment the various components of UV LED 100 may include the following material compositions (among others not discussed to avoid obscuring certain aspects of the disclosure). The composition of tunnel junction 107 will be discussed separately in connection with FIGS. 2A-3, and 6A-6D.

First n-type semiconductor region 101 may include Al(x)Ga(1-x-y)In(y)N. This semiconductor structure may have a bandgap larger than that of the quantum wells which, in some embodiments, may be incorporated in active region 103. First n-type semiconductor region 101 may also include superlattices, i.e. periodic array of layers with alternating compositions. Further, first n-type semiconductor region 101 may be Si or Ge doped to impart the n-type character.

Active region 103 may include a heterostructure composed of Al(x)Ga(1-x-y)In(y)N. The heterostructure may have multiple quantum wells having smaller bandgap regions (smaller Al molar fraction, or alternatively increased In molar fraction), cladded by larger-bandgap barriers (larger Al content) disposed between the individual quantum wells. One of ordinary skill in the art will appreciate the greater the percentage of Al in AlGaInN structures, the larger the bandgap (ranging from ˜0.7 ev for pure InN and ˜6 eV for AN). The quantum well count in active region 103 could be 1-10 (or more), and quantum well thickness could range from 1-20 nm. The barrier thickness may range from 1-20 nm. Moreover, active region 103 may also include quantum dots, quantum wires, quantum disks, etc., as active elements embedded in a wide band gap material.

First p-type semiconductor region 105 may include Al(x)Ga(1-x-y)In(y)N, with a bandgap larger than that of the quantum wells incorporated in active region 103. Similar to first n-type semiconductor region, first p-type semiconductor region 105 may include superlattices. First p-type semiconductor region 105 may also be Mg doped to impart the p-type character.

Lastly, second n-type semiconductor region 109 may include a similar structure as first n-type semiconductor region 101 (discussed above). And first contact 113 and second contact 111 may include metals/alloys such as Al, Ti/Al, W/Al, to name a few.

In the depicted embodiment, tunnel junction 107 is used as a “charge conversion layer” to provide holes to UV LED 100. The N layers (101 and 109) are contacted and the tunnel junction is operated in reverse bias to forward bias the PN junction surrounding active region 103. Tunnel junction 107 allows UV LED 100 to be fabricated without contact problems: a p-type contact that is resistive to AlGaN is eliminated, and the contact that replaces it absorbs less light than using a p-type GaN contact layer. In other words, contacting active region 103 with tunnel junction 107 allows for UV LED 100 to be fabricated without (a) an electrode that makes poor electrical contact to the materials in active region 103 or (b) an electrode that absorbs much of the UV light emitted from active region 103. Thus, the device architecture disclosed here represents a meaningful increase in the efficiency of UV emitting LEDs.

FIG. 2A is an illustration of a two layer tunnel junction 207A for the ultraviolet light emitting diode in FIG. 1, in accordance with an embodiment of the disclosure. As depicted tunnel junction 207A includes second p-type semiconductor region 215 (e.g., Al_{0.65}Ga_{0.35}N:Mg; [Mg]˜1e20 cm⁻³) and third n-type semiconductor region 217 (e.g., Al_{0.65}Ga_{0.35}N:Si: [Si]˜1e20cm⁻³), which may be P+ (e.g., Mg) and N+ (e.g., Si) doped, respectively. In some embodiments, both of these semiconductor materials are degenerately doped to allow charge carriers to tunnel between conduction/valence bands and, under an applied bias, create overlap between empty and full states. Second p-type semiconductor region 215 is disposed between a first p-type semiconductor region (e.g., first p-type semiconductor region 105) and third n-type semiconductor region 217. In some embodiments, the materials in tunnel junction 207A may have a gradated elemental composition. In other words, the transition between second p-type semiconductor region 215 and third n-type semiconductor region 217 occurs gradually. This graded alloy compensation may improve ionization of deep acceptor Mg. Alternatively, tunnel junction 207A may have a step-like composition at the interface of second p-type semiconductor region 215 and third n-type semiconductor region 217 to induce charge (lower Al in third n-type semiconductor region 217 in (0001) oriented layers, for example). In one embodiment, the layers surrounding tunnel junction 207 (e.g., first p-type semiconductor region 105 and second n-type semiconductor region 109 in FIG. 1) may have a wider bandgap than one or both of second p-type semiconductor region 215 and third n-type semiconductor region 217. However, in a different embodiment, the semiconductor materials in tunnel junction 207A may have bandgaps that are wider than, or the same as, the surrounding materials.

One of ordinary skill in the art will appreciate that while second p-type semiconductor region 215 and third n-type semiconductor region 217 are referred to as the “tunnel junction” the actual tunneling of charge carriers occurs in a narrow portion of this structure. Second p-type semiconductor region 215 and third n-type semiconductor region 217 are the semiconductor structures used to facilitate charge carrier tunneling in a small portion of tunnel junction 207A. Tunnel junction 207A includes an electrical potential, where the charge carriers pass through the electrical potential via quantum tunneling. Accordingly, since these structures are used to form the tunneling functionality, this disclosure refers to them collectively as the “tunnel junction”.

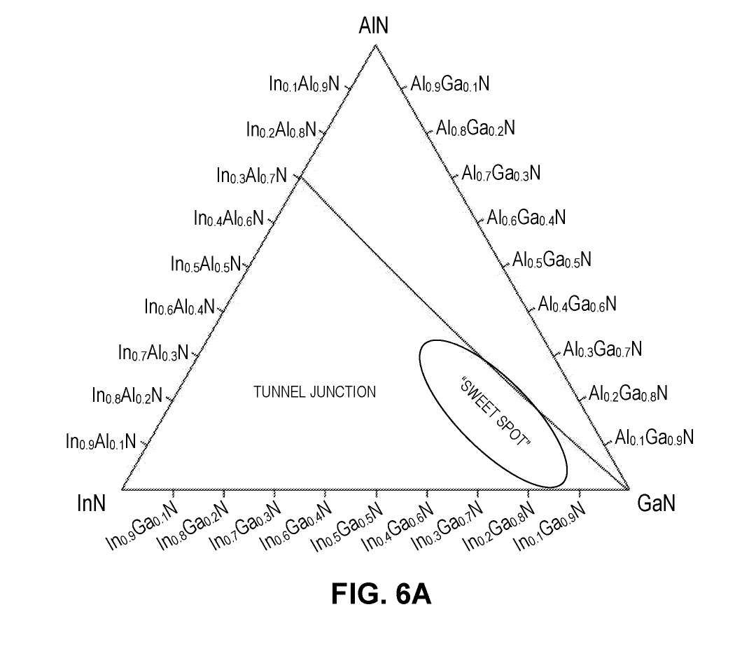

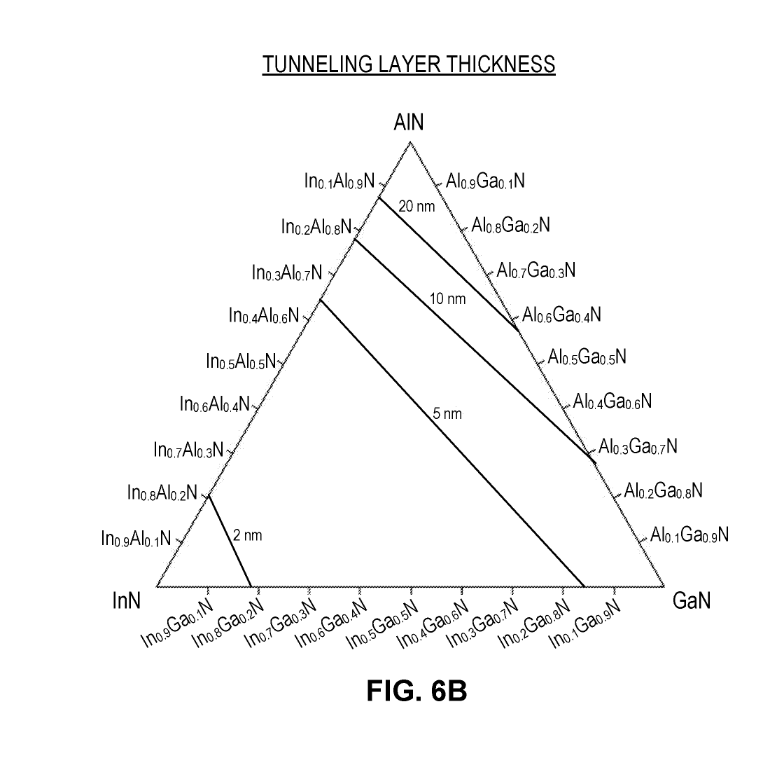

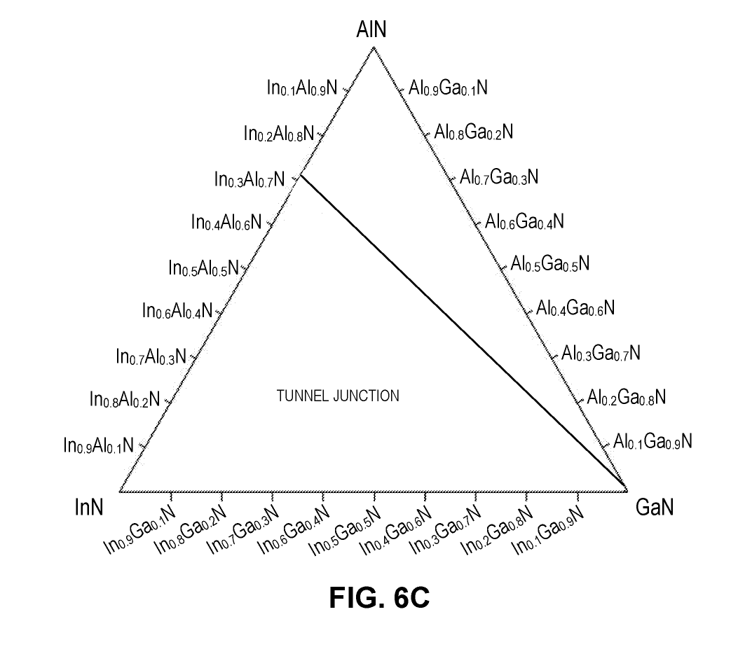

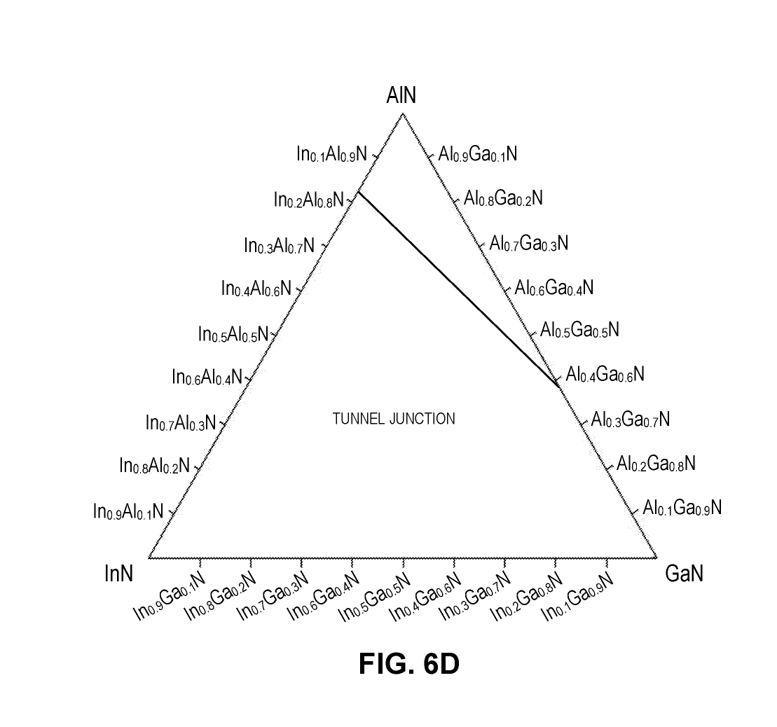

FIG. 2B is an illustration of a three layer tunnel junction 207B for the ultraviolet light emitting diode in FIG. 1, in accordance with an embodiment of the disclosure. Tunnel junction 207B is similar in many respects to tunnel junction 207A; however, tunnel junction 207B includes narrow bandgap semiconductor region 219 (e.g., In_{0.1}Ga_{0.9}N:Mg; [Mg]˜1e18 cm⁻³, see also FIG. 6A) disposed between second p-type semiconductor region 215 (e.g., Al_{0.65}Ga_{0.35}N:Mg; [Mg]˜1e20 cm⁻³) and third n-type semiconductor region 217 (e.g., Al_{0.65}Ga_{0.35}N:Si; [Si]˜1e20 cm⁻³). Narrow bandgap semiconductor region 219 has a narrower bandgap than second p-type semiconductor region 215 and third n-type semiconductor region 217. Narrow bandgap semiconductor region 219 may include, for example, GaN, AlInGaN, InGaN and may be 1-10 nm thick. The structure depicted uses polarization to increase the electric field in tunnel junction 207B. The three-layer tunnel junction 207B includes two layers with substantially the same composition (one p-type, e.g., second p-type semiconductor region 215, and one n-type, e.g., third n-type semiconductor region 217) surrounding a second layer having a different composition (e.g., narrow bandgap semiconductor region 219). Third n-type semiconductor region 217 may be an Mg stopping layer (e.g., an In containing layer to getter, which may contain a different dopant such as Ge). The compositions of second p-type semiconductor region 215/third n-type semiconductor region 217 and narrow bandgap semiconductor region 219 have different polarizations (spontaneous+piezoelectric components). At the ½ interface, a sheet charge with magnitude Q=P2−P1 exists, where P2 and P1 are the polarizations of the surrounding materials (second p-type semiconductor region 215/third n-type semiconductor region 217) and the center material (narrow bandgap semiconductor region 219), respectively. At the interface of these materials, the charge is sheet −Q. The thickness of the intermediate layer (d2) should be chosen so that (P2−P1)(d2/eps2)=Eg 1/q, where eps2 is the permittivity of the surrounding materials, and Eg 1 is the bandgap of the center material. Generally the strong polarization exploited here occurs in the wurtzite phase of the nitrides and the polarization is predominantly electrical.

FIG. 2C is an illustration of a four layer tunnel junction 207C for the ultraviolet light emitting diode in FIG. 1, in accordance with an embodiment of the disclosure. Tunnel junction 207C is similar in many respects to tunnel junction 207B; however, tunnel junction 207C includes third p-type semiconductor region 221 so that second p-type semiconductor region 215 is disposed between third p-type semiconductor region 221 and narrow bandgap semiconductor region 219. However, one of ordinary skill in the art will appreciate that third p-type semiconductor region 221 may be replaced with an n-type semiconductor region (on the other side of the tunnel junction), in accordance with the teachings of the present disclosure. Second p-type semiconductor region 215 may have a higher density of free charge carriers (more heavily doped) than third p-type semiconductor region 221. This four layer structure contemplates an Mg control layer before the polarized layer. In this case the purpose of second p-type semiconductor region 215 is to tailor the profile of Mg in the tunnel junction, and increase the Mg concentration in the immediate vicinity of where tunneling of charge carriers actually occurs. In other words, a magnesium concentration in tunnel junction 207C increases in a direction towards second p-type semiconductor region 215. Alternatively, second P-type semiconductor region 215 may be used as an intermediate hole well in close proximity to the location of charge carrier tunneling.

FIG. 2D is an illustration of a five layer tunnel junction 207D for the ultraviolet light emitting diode in FIG. 1, in accordance with an embodiment of the disclosure. Tunnel junction 207D is similar in many respects to tunnel junction 207C; however, tunnel junction 207D includes fourth n-type semiconductor region 223 so that third n-type semiconductor region 217 is disposed between fourth n-type semiconductor region 223 and narrow bandgap semiconductor region 219. In some embodiments third n-type semiconductor region 217 may have high Si concentrations. In other words, a silicon concentration in the tunnel junction increases in a direction of the third n-type semiconductor region. Generally, high Si concentrations may roughen semiconductor layers, so fourth n-type semiconductor region 223 could be considered a morphology recovery layer. Similar to other embodiments, layers may be graded in composition. Third n-type semiconductor region 217 may also be considered an electron well.

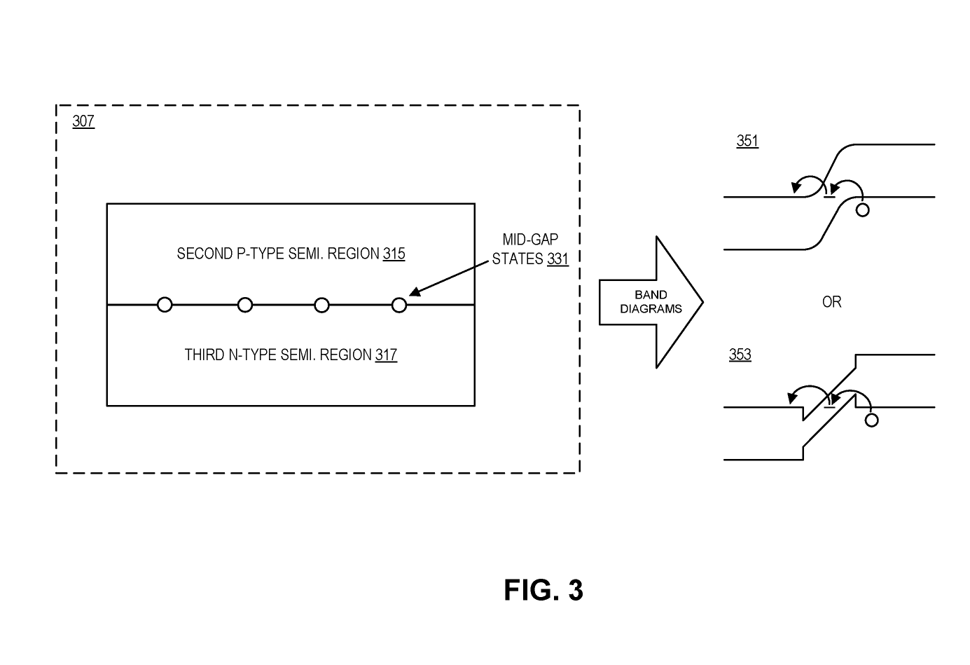

FIG. 3 is an illustration of a tunnel junction 307 and accompanying band diagrams 351/353 for the ultraviolet light emitting diode in FIG. 1, in accordance with an embodiment of the disclosure. In the depicted embodiment, tunnel junction 307 is a two layer tunnel junction (like the tunnel junction depicted in FIG. 2A); however, tunnel junction 307 has mid-gap states 331 disposed between second p-type semiconductor region 315 and third n-type semiconductor region 317. Mid-gap states 331 allow for increased tunneling current at a given bias applied between second p-type semiconductor region 315 and third n-type semiconductor region 317, by providing intermediate states between second p-type semiconductor region 315 and third n-type semiconductor region 317 where charge carriers may dwell. For example, as illustrated in band diagram 351, a mid-gap state 331 is illustrated as an open space in the middle of the p-n junction. Charge carriers can “hop” from one semiconductor material to mid-gap state 331 and then to the other semiconductor material. This increases the overall tunneling probability of electrons in the valence band of second p-type semiconductor region 315 to the empty states in the conduction band of third n-type semiconductor region 317. Band diagram 353 depicts the same phenomenon just with semiconductor materials having a different composition/density of states. In some embodiments, mid-gap states 331 may include at least one of carbon atoms, magnesium atoms, point defects in a semiconductor crystal lattice, or engineered states such as laterally inhomogeneously deposited narrow bandgap material in the form of quantum dots or alternate crystal structures consisting of rare earth atoms. One of ordinary skill in the art will appreciate that this method of potentially improving tunnel junction 307 may be applied to any of the embodiments of the tunnel junction in this disclosure. The position of the layer in the tunnel junction may be adjusted to achieve maximum tunnelling current with the minimum bias. For example, for a layer consisting of a state closer to the valence band, the layer may be positioned closer to the nominal p-type bulk layer within the tunnelling layer to achieve the highest resonance. The tunneling layer may include multiple types of mid-gap states to further enhance the tunneling current (for example, one layer with a state close to the valence band, one layer with a state close to the conduction band, and one layer with a state in the mid-gap, with each layer spatially separated in the tunneling region).

In the band diagrams 351/353 illustrated, under a reverse bias, the valence band energy of second p-type semiconductor region 315 is greater than or equal to a conduction band energy of third n-type semiconductor region 317. Thus charge carriers jump from the valence band of second p-type semiconductor region 315 into the conduction band of third n-type semiconductor region 317 through the tunnel junction.

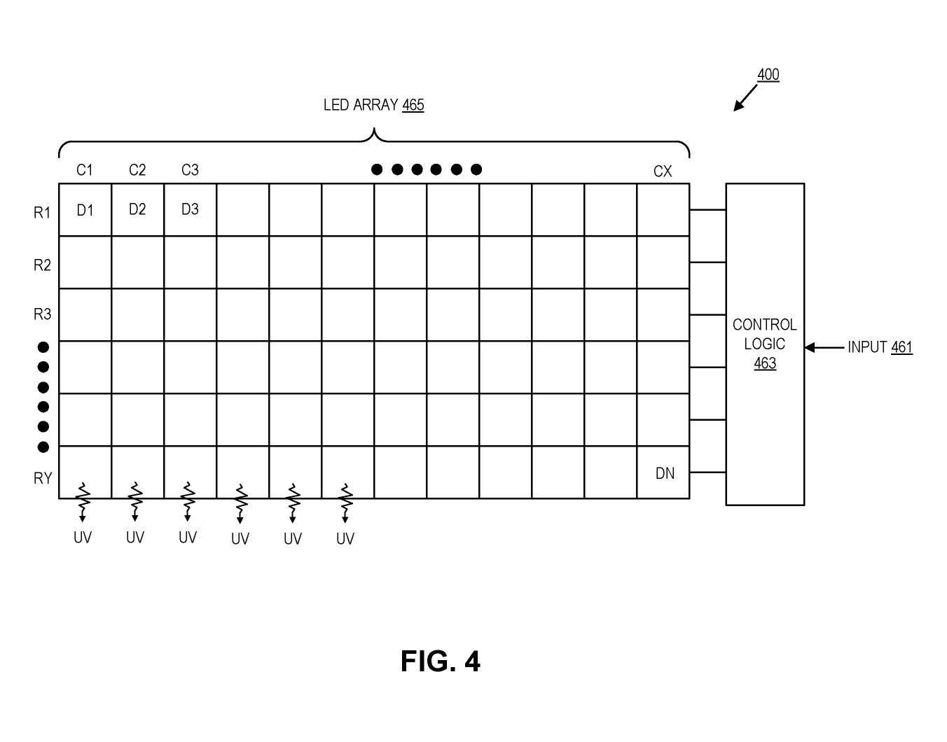

FIG. 4 is an illustration of a system 400 for ultraviolet light emission which may contain the ultraviolet light emitting diode in FIG. 1, in accordance with an embodiment of the disclosure. UV LED display system 400 includes UV LED array 465, control logic 463, and input 461. In one embodiment, UV LED array 465 is a two-dimensional array including a plurality of UV LEDs (e.g., D1, D2 . . . , DN) where one or more of LEDs (D1, D2 . . . , DN) may include LED 100. As illustrated, diodes are arranged into rows (e.g., rows R1-RY) and columns (e.g., columns C1-CX) to project UV light. However, it should be noted that the rows and columns do not necessarily have to be linear and may take other shapes. LEDs in sub-groups may be activated at different times and intensities such that the on-off times are varied. Also in some embodiments a portion of LEDs in the system may emit visible light to alert the user that the UV light is on; various groups of LEDs in UV LED array 465 may be turned on at different times. Further, UV LED display system 400 may emit a static pattern or may emit an active UV emission pattern depending on the data received from control logic 463.

In one embodiment, UV LED array 465 is controlled by control logic 463 coupled to the plurality of LEDs. Control logic 463 may include a processor (or microcontroller), switching power supply, etc. The processor or microcontroller may control individual LEDs in UV led array 465, or control groups of LEDs.

In the depicted embodiment, UV LED display system 400 includes input 461. Input 461 may include user input via buttons, USB port, wireless transmitter, HDMI port, etc. Input 461 may also include software installed on control logic 463 or data received from the internet or other source.

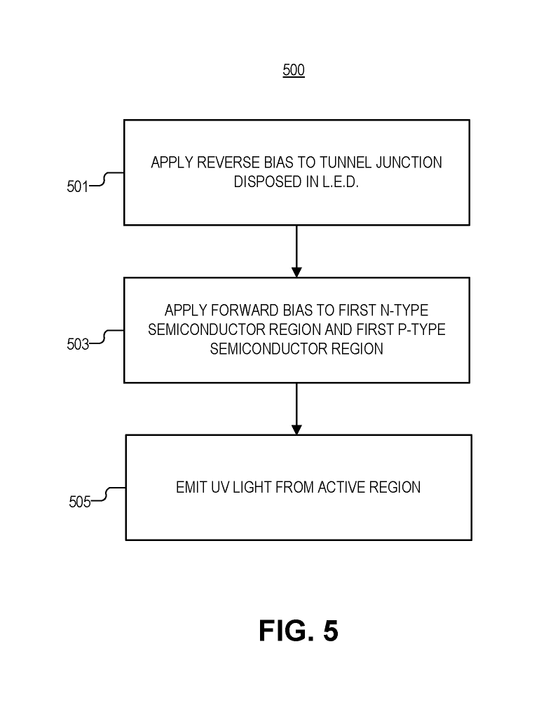

FIG. 5 illustrates a method 500 of emitting ultraviolet light from a light emitting diode, in accordance with an embodiment of the disclosure. The order in which some or all of process blocks 501-505 appear in method 500 should not be deemed limiting. Rather, one of ordinary skill in the art having the benefit of the present disclosure will understand that some of method 500 may be executed in a variety of orders not illustrated, or even in parallel. Additionally, method 500 may include additional blocks or have fewer blocks than shown, in accordance with the teachings of the present disclosure.

Block 501 shows applying a reverse bias to a tunnel junction disposed in the LED (which may result in Zener-type tunneling). In one embodiment, charge may be injected into the LED using a first electrical contact and a second electrical contact, where the first electrical contact is coupled to the first n-type semiconductor region so that the first n-type semiconductor region is disposed between the first electrical contact and the active region. Similarly, the second electrical contact is coupled to the second n-type semiconductor region so that the second n-type semiconductor region is disposed between the second electrical contact and the tunnel junction.

Block 501 depicts applying (simultaneously with applying the reverse bias to the tunnel junction) a forward bias to both a first n-type semiconductor region and a first p-type semiconductor region surrounding an active region of the light emitting diode. In one embodiment this may include injecting charge carriers into the active region through the tunnel junction to emit the UV light. This is because in this embodiment the first p-type semiconductor region is disposed between the active region and the tunnel junction. In another or the same embodiment, charge carriers may be transported across the tunnel junction using mid-gap states disposed between a p-n junction in the tunnel junction.

Block 505 illustrates emitting the UV light from the active region in response to the forward bias applied to the first n-type semiconductor region and the first p-type semiconductor region. In one embodiment a majority of light emitted from the LED is the UV light.

FIGS. 6A-6D illustrate ternary composition diagrams for tunneling layers in several of the tunnel junction architectures depicted, in accordance with embodiments of the disclosure. One of ordinary skill in the art will realize that these diagrams are not exhaustive of the compositions that may be used to form the tunneling layer in the UV LEDs of the instant disclosure.

FIG. 6A shows the composition of the tunneling layer in a three layer tunnel junction (e.g., region 219 of FIG. 2B). The triangle in the diagram labeled “tunnel junction” represents the atomic fractions of Al, Ga, and In that may yield a high-performance tunneling layer. As shown the upper bound is approximately governed by the equation AlₓIn_{y}Ga_{1-x-y}N, where x(z)=0.7 z, y(z)=0.3 z, where z ranges from 0 to 1. The depicted composition diagram was calculated using a tunnel junction figure of merit (FOM), where a FOM<10 typically makes for a quality tunnel junction. The model also contemplates a UV LED that is grown on a GaN substrate. In general, the further left and down in the depicted diagram, the higher the tunneling probability. A “sweet spot” (balancing material growth, lattice strain, and tunneling) may fall somewhere in the lower right corner.

FIG. 6B illustrates an estimated tunneling layer thickness for the various compositions in FIG. 6A. As shown in the lower left corner, the tunneling layer may be 2 nm thick with a fractional composition of In in the range of 0.8, and an Al and/or Ga composition of 0.2. Up and to the right of the diagram, the thickness of the tunneling layer increases to 5 nm for In compositions between 0.2 and 0.4 (and corresponding fractions of Al and/or Ge). For compositions approaching pure AN, the tunneling layer may need to be 10-20 nm thick. One of ordinary skill in the art will appreciate that the thicknesses here are a guide. The layer may be thinner with high doping at the edges, and thicker with lower doping, in general. The employed thickness would be determined empirically in all cases. The thickness indicated is the thickness of the tunneling layer that sustains a dipole moment equivalent to the surrounding material's band gap.

FIG. 6C shows the composition of the tunneling layer in a four layer tunnel junction (e.g., region 219 of FIG. 2C) calculated using the same FOM as FIG. 6A. As shown, the triangle in the diagram labeled “tunnel junction” may yield a high performance tunneling layer, and this area of the plot has shifted to be slightly larger than in the diagram for the three layer structure (FIG. 6A). The diagram in FIG. 6C assumes 63% AlN AlGaN bulk layers, on an AlN substrate, and an Al_{0.60}In_{0.05}N layer for the third p-type semiconductor region (e.g., region 221). In this example, the third p-type semiconductor region's purpose may be a doping management layer, with a side benefit of altering the band gap of the edges of the tunnel junction by a small amount.

FIG. 6D shows the composition of the tunneling layer in a three layer tunnel junction with mid-gap states (e.g., region 219 of FIG. 2B but with the mid-gap states of FIG. 3) calculated using the same FOM as FIG. 6A. A shown, the addition of mid-gap states pushes increases the possible material compositions that may yield a high performance tunnel junction.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

1. A light emitting diode (LED) to emit ultraviolet (UV) light, comprising:
a first n-type semiconductor region;
a first p-type semiconductor region;
an active region disposed between the first n-type semiconductor region and the first p-type semiconductor region, wherein in response to a bias applied across the light emitting diode, the active region emits the UV light;
a tunnel junction, wherein the first p-type semiconductor region is disposed between the active region and the tunnel junction, and wherein the tunnel junction is electrically coupled to inject charge carriers into the active region through the first p-type semiconductor region; and
a second n-type semiconductor region, wherein the tunnel junction is disposed between the second n-type semiconductor region and the first p-type semiconductor region.

2. The LED of claim 1, wherein the tunnel junction includes:
a second p-type semiconductor region; and
a third n-type semiconductor region, wherein the second p-type semiconductor region is disposed between the first p-type semiconductor region and the third n-type semiconductor region.

3. The LED of claim 2, wherein an interface between the second p-type semiconductor region and the third n-type semiconductor region includes a gradated elemental composition.

4. The LED of claim 2, wherein a first bandgap of the first p-type semiconductor region is larger than a second bandgap of the second p-type semiconductor region, and wherein a third bandgap of the second n-type semiconductor region is larger than a fourth bandgap of the third n-type semiconductor region.

5. The LED of claim 2, further comprising mid-gap states disposed between the second p-type semiconductor region and the third n-type semiconductor region, wherein the mid-gap states lower a barrier for the charge carriers to move from the second p-type semiconductor region to the third n-type semiconductor region.

6. The LED of claim 5, wherein the mid-gap states include at least one of carbon atoms, magnesium atoms, point defects in a semiconductor crystal lattice, quantum dots, or rare earth element atoms.

7. The LED of claim 2, further comprising a narrow bandgap semiconductor region disposed between the second p-type semiconductor region and the third n-type semiconductor region, wherein the narrow bandgap semiconductor region has a narrower bandgap than the second p-type semiconductor region and the third n-type semiconductor region.

8. The LED of claim 7, wherein an upper bound of an atomic fraction of Al and In in the narrow bandgap semiconductor region is AlₓIn_{y}Ga_{1-x-y}N, where x(z)=0.7 z, y(z)=0.3 z, where z ranges from 0 to 1, and wherein a thickness of the narrow bandgap region is between 1 and 10 nm.

9. The LED of claim 7, further comprising a third p-type semiconductor region, wherein the second p-type semiconductor region is disposed between the third p-type semiconductor region and the narrow bandgap semiconductor region, and wherein the second p-type semiconductor region has a higher density of free charge carriers than the third p-type semiconductor region.

10. The LED of claim 9, wherein a magnesium concentration in the tunnel junction increases in a direction towards the second p-type semiconductor region.

11. The LED of claim 9, further comprising a fourth n-type semiconductor region, wherein the third n-type semiconductor region is disposed between the fourth n-type semiconductor region and the narrow bandgap semiconductor region, wherein the third n-type semiconductor region has a higher density of free charge carriers than the fourth n-type semiconductor region.

12. The LED of claim 11, wherein a silicon concentration in the tunnel junction increases in a direction of the third n-type semiconductor region.

13. The LED of claim 1, wherein the tunnel junction includes an electrical potential, and wherein the charge carriers pass through the electrical potential via quantum tunneling.

14. A system for ultraviolet light (UV) emission, comprising:
a plurality of light emitting diodes (LEDs) arranged into an array, wherein at least a portion of the LEDs in the plurality of LEDs include:
a first n-type semiconductor region;
a first p-type semiconductor region;
an active region disposed between the first n-type semiconductor region and the first p-type semiconductor region, wherein in response to a bias applied across the light emitting diode, the active region emits the UV light; and
a tunnel junction, wherein the first p-type semiconductor region is disposed between the active region and the tunnel junction, and wherein the tunnel junction is electrically coupled to inject charge carriers into the active region through the first p-type semiconductor region.

15. The system of claim 14, wherein semiconductor materials in the tunnel junction have a narrower bandgap than the first p-type semiconductor region and a second n-type semiconductor region, wherein the tunnel junction is disposed between the first p-type semiconductor region and the second n-type semiconductor region.

16. The system of claim 14, further comprising a second n-type semiconductor region electrically coupled to the tunnel junction, wherein the tunnel junction is disposed between the second n-type semiconductor region and the first p-type semiconductor region, and wherein the tunnel junction includes a second p-type semiconductor region and a third n-type semiconductor region.

17. The system of claim 16, further comprising a narrow bandgap semiconductor region disposed between the second p-type semiconductor region and the third n-type semiconductor region, wherein the narrow bandgap semiconductor region has a narrower bandgap than the second p-type semiconductor region and the third n-type semiconductor region.

18. The system of claim 14, further comprising control logic coupled to the plurality of LEDs to control the bias across the plurality of LEDs.

19-24. (canceled)
